(19) United States
(12) Patent Application Publication
(10) Pub. No.: US 2019/0166716 A1
(43) Pub. Date: May 30, 2019

(54) HEAT DISSIPATING DEVICE FOR MEDICAL IMAGING APPARATUS

(71) Applicant: SHENYANG NEUSOFT MEDICAL SYSTEMS CO., LTD., Shenyang (CN)

(72) Inventors: Shuangxue LI, Shenyang (CN); Jun YU, Shenyang (CN)

(21) Appl. No.: 16/118,037

(22) Filed: Aug. 30, 2018

(30) Foreign Application Priority Data
Nov. 29, 2017 (CN) 201711226414.6

(51) Int. Cl. H05K 7/20

(52) U.S. Cl. CPC H05K 7/20145

(57) ABSTRACT

A heat dissipating device for a medical imaging apparatus is provided, comprising an air director fixedly provided on a detector of the medical imaging apparatus and a housing in communication with an air source, wherein the air director comprises an air inlet, an air outlet, and an air duct communicating the air inlet with the air outlet. The air outlet is in communication with an air supply unit provided on the detector. The housing comprises at least one inlet in communication with the air source, an air chamber in communication with the inlet, and an outlet in communication with the air chamber. In addition, the outlet provided in the housing is in communication with the air outlet of the air director.

### CROSS REFERENCE TO RELATED APPLICATIONS

This application claims priority to Chinese Patent Application No. 201711226414.6 filed on Nov. 29, 2017, the entire content of which is incorporated herein by reference in its entirety for all purposes.

### TECHNICAL FIELD

The present disclosure relates to a heat dissipating device for a medical apparatus.

### BACKGROUND

With the development of medical imaging apparatuses such as a Computed Tomography (CT) scanner, a number of slices of a detector system in the CT scanner is increasing, and, consequently, a number of pixel units of the detector are also increasing, causing the entire CT scanner to generate a larger amount of heat. For other medical imaging apparatuses, similar problems may also exist if there are also detector components rotating during operation.

NEUSOFT MEDICAL SYSTEMS CO., LTD. (NMS), founded in 1998 with its world headquarters in China, is a leading supplier of medical device, medical IT solutions, and healthcare services. NMS supplies medical device with a wide portfolio, including CT, Magnetic Resonance Imaging (MRI), digital X-ray machine, ultrasound, Positron Emission Tomography (PET), Linear Accelerator (LINAC), and biochemistry analyser. Currently, NMS' products are exported to over 60 countries and regions around the globe, serving more than 5,000 renowned customers. NMS's latest successful developments, such as 128 Multi-Slice CT Scanner System, Superconducting MRI, LINAC, and PET products, have led China to become a global high-end medical device producer. As an integrated supplier with extensive experience in large medical device, NMS has been committed to the study of avoiding secondary potential harm caused by excessive X-ray irradiation to the subject during the CT scanning process.

### BRIEF DESCRIPTION OF DRAWINGS

FIG. 1 is an exploded diagram illustrating a heat dissipating device for a detector of a CT scanner according to an example of the present disclosure.

FIG. 2 is a rear isometric diagram illustrating an air director shown in FIG. 1.

FIG. 3 is a front isometric diagram illustrating the air director shown in FIG. 1.

FIG. 4 is a rear isometric diagram of the air director and a housing shown in FIG. 1 fitted together.

FIG. 5 is a side sectional diagram illustrating part of the structure shown in FIG. 4.

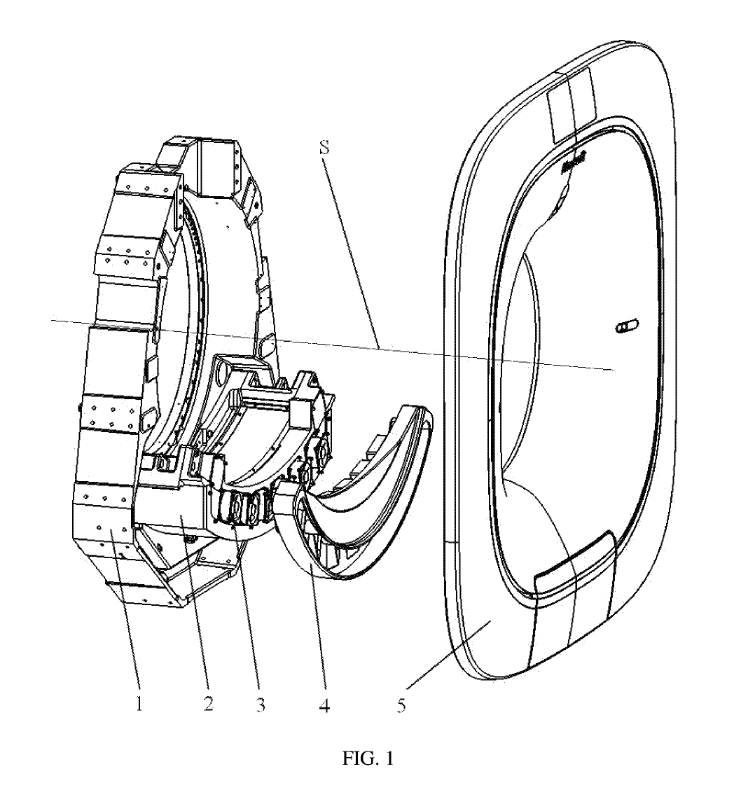

A one-to-one corresponding relationship between component names and reference numerals in FIG. 1 to FIG. 5 is as follows:

a CT scanner rotating system 1, a detector 2, an air supply unit 3, an air director 4, an outer wall 41 of the air director 4, an air inlet 411, an air outlet 42, a mounting base 43, a housing 5, an inlet 51, an air distributing hole 521, an air chamber 53, an inner wall 52 of the air chamber 53, and a rotating axis S.

### DETAILED DESCRIPTION

After a temperature of an entire CT scanner increases, on one hand, thermal expansion and deformation of internal mechanical structure of the CT scanner may affect detection accuracy and on the other hand electronic noise of a detector system may increase, thereby reducing a signal-to-noise ratio of collected signals and affecting the image quality of the CT scanner. Therefore, the detector of the CT scanner is to be maintained at a relatively stable and lower temperature by heat dissipation for the detector of the CT scanner.

Heat dissipation may be performed for the detector by taking in air from a front chamber of a host of the CT scanner or a water-cooling system may be provided in a housing chamber of a main gantry to indirectly maintain a stable temperature of the detector system. But the heat dissipation effect of both of the above two manners is not good.

Without loss of generality, a heat dissipating device of a detector of a CT scanner is taken as an example for illustration herein. It may be understood that a heat dissipating device of a similar structure may also be used for detectors of other medical apparatuses, and may be changed adaptively according to the structure of a specific device, which will not be described one by one.

FIG. 1 is an exploded diagram illustrating a heat dissipating device for a detector of a CT scanner according to an example of the present disclosure. As shown in FIG. 1, the CT scanner may include a CT scanner rotating system 1 and a detector 2, and the heat dissipating device of the detector 2 may include an air supply unit 3 mounted on the detector 2 and an air director 4 fixedly disposed on the detector 2.

The CT scanner rotating system 1 may drive the detector 2 to rotate around the rotating axis S to complete a CT scan. The CT scanner rotating system 1 in FIG. 1 shows only a part of the CT scanner rotating system 1 related to the detector 2.

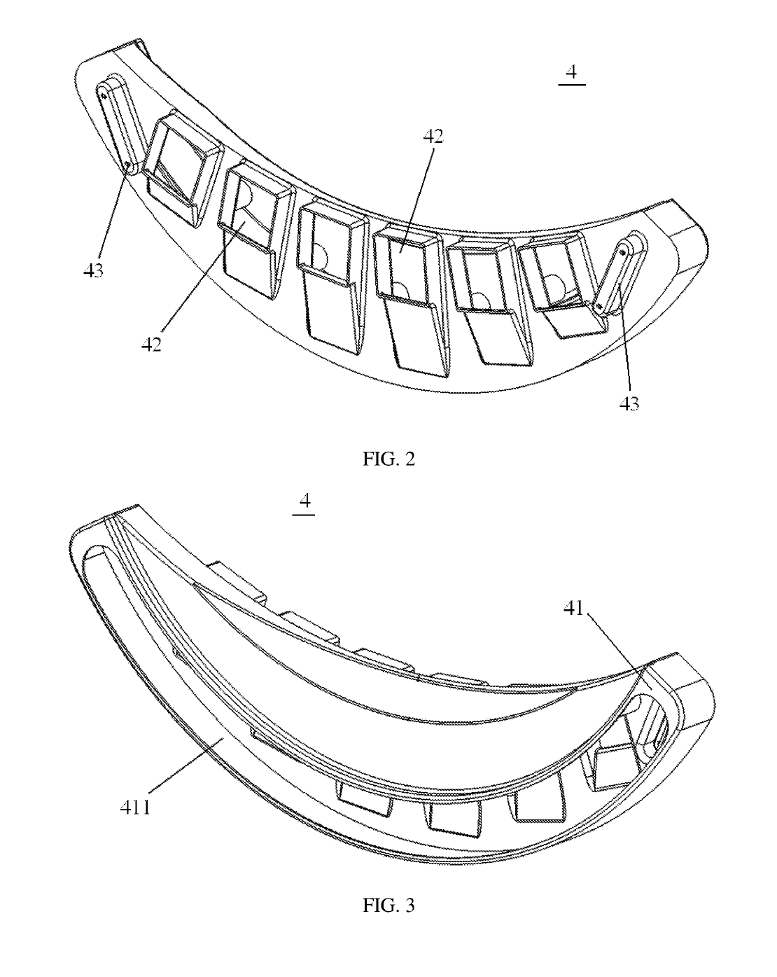

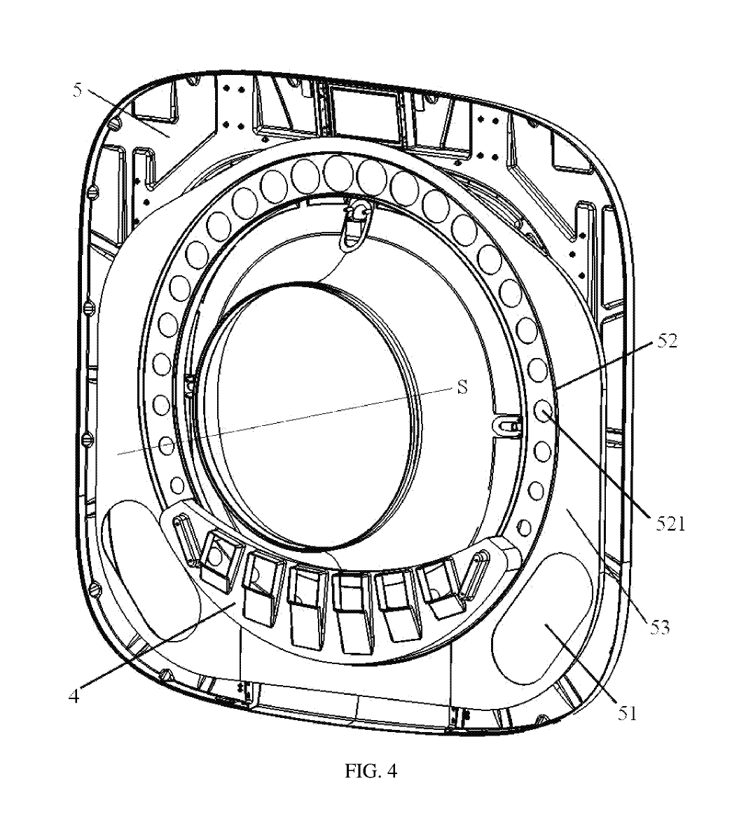

FIG. 2 is a rear isometric diagram illustrating an air director shown in FIG. 1. FIG. 3 is a front isometric diagram illustrating the air director shown in FIG. 1. As shown in FIG. 2 and FIG. 3, the air director 4 includes an air inlet 411, an air outlet 42, and an air duct communicating the air inlet 411 with the air outlet 42, where the air outlet 42 of the air director 4 is in communication with the air supply unit 3.

The heat dissipating device may further include an air source and an air chamber structure formed in the housing 5 of the CT scanner. The housing 5 includes an inlet 51 in communication with the air source, an air chamber 53 in communication with the inlet 51, and an outlet in communication with the air chamber 53. The outlet is in communication with the air outlet 42 of the air director 4. Obviously, the outlet communicates with the air outlet 42 through the air inlet 411 of the air director 4.

It is to be noted that for a CT scanner, the above air chamber structure is usually in a front housing of the housing 5. In an example, at least a portion of the front housing is a double-layered structure to form the air chamber 53. In another example, the entire front housing is a double-layered structure to form the air chamber 53. In addition, for different devices, the air chamber structure may be provided at different positions of the housing 5 and is not limited to the front housing, so as to facilitate the formation of an air duct structure for heat dissipation.

According to the heat dissipating device of the CT scanner provided by this example, the air director 4 is fixedly provided on the detector 2 of the CT scanner, and the air chamber 53 in communication with the air source is provided in the housing 5. The air director 4 has an air outlet 42 in communication with the air supply unit 3 mounted on the detector 2 and an air inlet 411 in communication with the air outlet 42. The outlet of the air chamber 53 is in communication with the air inlet 411 of the air director 4. In this way, air from an external air source may be directly led to the air supply unit 3 of the detector 2 through the air chamber 53 of the housing 5 and the air director 4. Since heat dissipating air is directly supplied from the external air source to the rotating detector 2, it may be effectively ensured that temperature-stable air is supplied to the detector 2 so as to form an air current with a relatively uniform temperature. Thus, the detector 2 may be maintained at a relatively stable operating temperature.

The air supply unit 3 mounted on the detector 2 may take many forms. For example, the air supply unit 3 may include one or more fans. An air supply opening of the air supply unit 3 may be formed by an air inlet opening of each of the fans. Of course, only one centralized air supply opening may be provided for the air supply unit 3.

In an example, as shown in FIG. 1, the air supply unit 3 may be provided with six fans, that is, the air supply unit 3 has six air supply openings, and the six air supply openings are arranged in an arc shape.

As shown in FIG. 1 and FIG. 2, a number of the air outlets 42 of the air director 4 may be a same as that of the air supply openings of the air supply unit 3, and a position of each of the air outlets 42 corresponds to that of each of the air supply openings one to one. For example, after the air director 4 is fixedly provided on the detector 2, the air outlets 42 of the air director 4 are in direct communication with the corresponding air supply openings of the air supply unit 3.

The air director 4 may be fixed to the detector 2 in a plurality of manners. For example, as shown in FIG. 2, mounting bases 43 may be provided at both ends of the air director 4 respectively, and mounting holes may be opened in the mounting bases 43. In this way, the air director 4 may be fixed to the detector 2 by penetrating a tightening piece such as a bolt through the mounting hole in the mounting bases and screwing the tightening piece into a corresponding mounting hole in the detector 2. This detachably connecting manner may facilitate maintenance and replacement of the air director 4. The air director 4 may also be fixed to the detector 2 in a welding manner or another fixing manner.

With reference to FIG. 3, the air inlet 411 may be provided on the outer wall 41 of the air director 4 and shaped into an arc. For example, the air inlet 411 may be in an arc shape concentric with the rotating axis S of the detector 2.

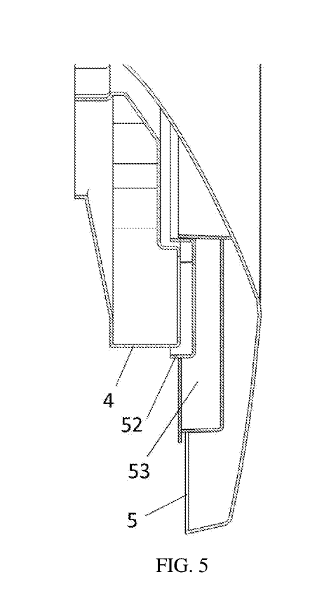

With reference to FIG. 4 and FIG. 5, the air chamber 53 formed in the housing 5 may have an inner wall 52. In this way, the outlet of the air chamber 53 may be opened in the inner wall 52 of the housing 5.

The outlet of the air chamber 53 may include one or more air distributing hole groups. Each of the air distributing hole groups may include a plurality of air distributing holes 521, and the plurality of air distributing holes 521 of each of the air distributing hole groups are arranged annularly. For example, the plurality of air distributing holes 521 of one air distributing hole group may be uniformly arranged in an annular-shape region concentric with the rotating axis S of the detector 2, where the centres of the plurality of air distributing holes 521 of each of the air distributing hole groups may be located on a circumference of a circle concentric with the rotating axis S of the detector 2.

The outer wall 41 of the air director 4 may be fitted with the inner wall 52 of the air chamber 53 formed in the housing 5 so that the air distributing holes 521 may be in direct communication with the air inlet 411. Obviously, after each of the components is assembled, the outer wall 41 of the air director 4 is substantially fitted with the inner wall 52 of the housing 5. In this way, the air distributing holes 521 formed in the inner wall 52 of the housing 5 may directly supply heat dissipating air transferred from the air source to the air inlet 411 of the air director 4.

Since the air director 4 is fixed on the detector 2 and the detector 2 rotates along with the CT scanner rotating system 1 during operation, the air director 4 may also rotate around the rotating axis S together with the detector 2. Thus, the air inlet 411 and each of the air distributing hole groups may be respectively arranged into a structure concentric with the rotating axis S as above, so that there will always be air distributing holes 521 communicating with the air inlet 411 of the air director 4 at any position to which the air director 4 rotates along with the detector 2. Thus, it may be ensured that the heat dissipating air is always transferred to the air director 4 during the operation of the detector 2, and is further transferred to the air supply unit 3 of the detector 2.

In the example shown in FIG. 4, only one air distributing hole group of a plurality of air distributing holes 521 is arranged annularly on the inner wall 52 of the housing 5. Of course, two or more air distributing hole groups may also be provided on the inner wall 52 of the air chamber 53.

It is to be noted that a number of the air distributing holes 521 of each of the air distributing hole groups may be set according to actual needs.

The outer wall 41 of the air director 4 may also be arranged into an arc-shaped structure concentric with the rotating axis S, which may facilitate the arrangement of the air inlet 411. The inner wall 52 of the air chamber 53 may be arranged into an annular plate-like structure concentric with the rotating axis S, which also facilitates the formation of the air distributing holes 521.

In the example shown in FIG. 4, two inlets 51 communicating with the air chamber 53 may be opened on the housing 5, and the two inlets 51 may be arranged symmetrically with respect to the rotation axis S of the detector 2.

The plurality of air distributing holes 521 of each of the air distributing hole groups may be provided in the following way: the closer the distributing holes 521 are to the inlet 51, the sparser the air distributing holes 521 are; and the further the distributing holes 521 are from the inlet 51, the denser the air distributing holes 521 are. In this way, when the air director 4 rotates along with the detector 2, the amount of air entering the air director 4 at any angle position may be equivalent. The reason is that the closer the air distributing holes 521 are to the inlet 51, the shorter a path along which the heat dissipating air runs through the inlet 51 and the air distributing holes 521 to the air inlet 411 of the air director 4 is, therefore, a relatively large amount of heat dissipating air flows into the air director 4. By arranging the air distributing holes 521 close to the inlet 51 relatively sparsely and arranging the air distributing holes 521 far from the inlet 51 relatively densely, the amount of the heat dissipating air received by the air director 4 when rotating to different positions may be relatively balanced.

The plurality of air distributing holes 521 of each of the air distributing hole groups may also be provided in the following way: the closer the air distributing holes 521 are to the inlet 51, the smaller the apertures of the air distributing holes 521 are; the further the air distributing holes 521 are from the inlet 51, the larger the apertures of the air distributing holes 521 are. In this way, when the air director 4 rotates along with the detector 2, the amount of air entering the air director 4 at any angle position may be equivalent.

The plurality of air distributing holes 521 of each of the air distributing hole groups may also be arranged by combining the above two manners: the closer the air distributing holes 521 are to the inlet 51, the sparser the air distributing holes 521 are, and the smaller the apertures of the air distributing holes 521 are; the further the air distributing holes 521 are from the inlet 51, the denser the air distributing holes 521 are, and the larger the apertures of the air distributing holes 521 are. In this way, a reasonable distribution may be achieved so that the amount of the heat dissipating air received by the air director 4 when rotating to any position is relatively equivalent. As shown in FIG. 4, the plurality of air distributing holes 521 are arranged this way.

In the example shown in FIG. 4, since two inlets 51 are provided on the housing 5, a relationship with the two inlets 51 may be taken into account when a plurality of air distributing holes 521 of each of the air distributing hole groups are arranged.

The outer wall 41 of the air director 4 may be fitted with the inner wall 52 of the housing 5, which may effectively reduce an amount of heat dissipating air that leaks from between the outer wall 41 of the air director 4 and the inner wall 52 of the housing 5 after entering the air chamber 53. However, during the rotation of the air director 4, the outer wall 41 of the air director 4 will rub against the inner wall 52 of the housing 53, which contributes to a particular degree of wear and tear to the outer wall 41 of the air director 41 and the inner wall 52 of the housing 5.

In an example, the outer wall 41 of the air director 4 may be in clearance fit with the inner wall 52 of the housing 5 so that the air director 4 does not come in contact with and rub against the inner wall 52 of the housing 5 when rotating. In this way, although there is leakage of heat dissipating air, wear and tear between the air director 4 and the inner wall 52 of the housing 5 may be effectively avoided, thereby prolonging the service life of the CT scanner effectively.

In fact, during the rotation of the air director 4, the heat dissipating air will also flow out from air distributing holes 521 that are not aligned with the air inlet 411 of the air director 4. A total amount of air supplied by the air source to the air chamber 53 is at least the sum of the amount of air required for the heat dissipation of the detector 2 and the amount of air leaked from the inner wall 52 of the housing 5. Here, the amount of air leaked from the inner wall 52 of the housing 5 may include the amount of air flowing out from the air distributing holes 521 that are not aligned with the air inlet 411 of the air director 4 and the amount of air leaked from the clearance between the outer wall 41 of the air director 4 and the inner wall 52 of the housing 5.

The outer wall 41 of the air director 4 may also be arranged into an annular structure concentric with the rotating axis S, and the air inlet 411 formed thereon may still take an arc shape. In this way, during the rotation of the air director 4, the air inlet 411 may be still in communication only with the air distributing holes 521 at a position corresponding to the air inlet 411, and a portion of the outer wall 41 of the air director 4 where air inlet 411 is not opened may block air distributing holes 521 that are not aligned and in communication with the air inlet 411 so as to effectively reduce the amount of leaked air and further reduce a requirement for the total amount of air of the air source.

The air source may be a fan provided in an air hood, and the inlet 51 of the housing 5 may be in direct communication with an air outlet of the air hood. In this way, for a CT scanner, the air director of the fan may be a front housing of a scanning gantry, and the inlet 51 of the housing 5 may be in direct communication with an air outlet of the front housing of the scanning gantry.

In addition, the air hood of the fan serving as the air source may also be provided separately. For example, the air hood may be provided outside the scanning gantry or outside the CT gantry. At this time, the inlet 51 of the housing 5 may be in communication with the air outlet of the air hood of the fan through an air supply duct. Further, an air conditioner may be provided in the air supply duct to perform processing, such as temperature stabilization, dehumidification, purification or pressure stabilization, on the air to enter the air chamber 53 of the housing 5.

Of course, it may be understood that the air source may also be an air supply machine such as a blower or a ventilator in addition to a fan.

The above are detailed descriptions of a heat dissipating device of a detector of a medical imaging apparatus provided in the present disclosure. Specific examples are utilized herein to set forth the principles and implementations of the present disclosure, and the descriptions of the above examples are merely meant to help understanding the method and the core idea of the present disclosure. It should be noted that a plurality of improvements and modifications may also be made to the present disclosure by those of ordinary skill in the art without departing from the principles of the present disclosure, and such improvements and modifications shall all fall into the scope of protection of the claims of the present disclosure.

What is claimed is:

1. A heat dissipating device for a medical imaging apparatus, comprising:
an air director provided on a detector of the medical imaging apparatus, wherein the air director comprises:
an air inlet;
an air outlet communicating with an air supply unit provided on the detector; and an air duct communicating the air inlet with the air outlet;
a housing, wherein the housing comprises:
at least one inlet in communication with an air source, an air chamber in communication with the inlet, and an outlet in communication with the air chamber, wherein the outlet is in communication with the air outlet through the air inlet.

2. The heat dissipating device according to claim 1, wherein the air supply unit comprises one or more air supply openings, a number of the air outlets of the air director corresponds to a number of the air supply openings of the air supply unit, and a position of each of the air outlets corresponds to a position of one of the air supply openings.

3. The heat dissipating device according to claim 2, wherein the air supply unit comprises one or more fans.

4. The heat dissipating device according to claim 3, wherein the air supply unit comprises six fans.

5. The heat dissipating device according to claim 1, wherein the air inlet is opened in an outer wall of the air director, and the air inlet is arranged into an arc shape concentric with a rotating axis of the detector.

6. The heat dissipating device according to claim 5, wherein the outlet is opened in an inner wall of the air chamber, the outlet comprises one or more air distributing hole groups, and each of the air distributing hole groups comprises a plurality of air distributing holes, and the plurality of air distributing holes of each of the air distributing hole groups are arranged in an annular-shape region concentric with the rotating axis of the detector.

7. The heat dissipating device according to claim 6, wherein the outer wall of the air director is in clearance fit with the inner wall of the housing.

8. The heat dissipating device according to claim 6, wherein the plurality of air distributing holes of each of the air distributing hole groups are provided in a following way:
the closer the air distributing holes are to the inlet, the sparser the air distributing holes are, the farther the air distributing holes are away from the inlet, the denser the air distributing holes are.

9. The heat dissipating device according to claim 6, wherein the plurality of air distributing holes of each of the air distributing hole groups are provided in a following way:
the closer the air distributing holes are to the inlet, the smaller the apertures of the air distributing holes are, the farther the air distributing holes are away from the inlet, the larger the apertures of the air distributing holes are.

10. The heat dissipating device according to claim 6, wherein the inner wall of the housing is an annular plate-like structure concentric with the rotating axis of the detector.

11. The heat dissipating device according to claim 5, wherein the outer wall of the air director is in an arc shape concentric with the rotating axis of the detector.

12. The heat dissipating device according to claim 5, wherein the outer wall of the air director is in an annular shape concentric with the rotating axis of the detector; and the air inlet is in an arc shape opened in the outer wall of the air director.

13. The heat dissipating device according to claim 5, wherein the housing comprises a plurality of inlets, the plurality of inlets are arranged symmetrically with respect to the rotating axis of the detector.

14. The heat dissipating device according to claim 1, wherein the inlet is in direct communication with an air outlet of the air source.

15. The heat dissipating device according to claim 1, wherein the inlet is in communication with an air outlet of the air source through an air supply duct.

16. The heat dissipating device according to claim 15, wherein the air supply duct is provided with an air conditioner.
